(19) United States
(12) Patent Application Publication
(10) Pub. No.: US 2024/0275131 A1
(43) Pub. Date: Aug. 15, 2024

(54) TUNABLE LONG COHERENCE LASER LOCKED TO A MICRORESONATOR VIA SELF-INJECTION

(71) Applicant: Soreq Nuclear Research Center, Yavne (IL)

(72) Inventors: Eyal Yacoby, Yavne (IL); Bruno Sfez, Yavne (IL)

(73) Assignee: Soreq Nuclear Research Center, Yavne (IL)

(21) Appl. No.: 18/567,125

(22) PCT Filed: Jun. 2, 2022
(86) PCT No.: PCT/IB2022/055165

§ 371 Date: Dec. 5, 2023

Related U.S. Application Data
(60) Provisional application No. 63/197,567, filed on Jun. 7, 2021.

(51) Int. Cl. H01S 5/0687; H01S 5/024; H01S 5/06; H01S 5/065; H01S 5/10

(52) U.S. Cl. CPC H01S 5/0687; H01S 5/02415; H01S 5/0612; H01S 5/0657; H01S 5/1014; H01S 5/1032; H01S 5/1042

(57) ABSTRACT

A multimode diode laser (with a single transverse mode) is optically locked to a single Whispering Gallery Mode (WGM) of a microresonator via self-injection feedback. The tunability of the WGM-locked laser is achieved by locking the diode laser to different WGMs of the microresonator.

### FIELD OF THE INVENTION

The present invention relates to tunable, long coherent length lasers.

### BACKGROUND OF THE INVENTION

Tunable, long coherent length laser sources are required for many applications such as spectroscopy, holographic metrology, quantum measurements, three-dimensional digital holographic metrology, as well as for medical applications, such as acousto-optic imaging.

Highly tunable (>200 nm) narrow linewidth lasers are available, where the state of the art lasers are based on a Littman-Metcalf configuration, in which spectral tuning is achieved by mechanical tuning of an internal back reflector mirror. However, the high cost and large sizes of these devices are a significant drawback. In contrast to the prior art, the present invention aims to provide a low cost and compact tunable laser device.

### SUMMARY OF THE INVENTION

The present invention provides a low cost and compact tunable single laser source. A multimode diode laser (with a single transverse mode) is optically locked to a single Whispering Gallery Mode (WGM) of a micro-resonator via self-injection feedback. The tunability of the WGM-locked laser is achieved by locking the diode laser to different WGMs of the microresonator. The WGMs are selected by tuning the temperature and polarization of the laser source. In addition, the WGMs are tuned mechanically, or by controlling the temperature of the microresonator using a feedback control system. Simultaneous control of the laser source temperature and of the microresonator's WGMs achieves a continuous tunability for the WGM-locked laser wavelength.

### BRIEF DESCRIPTION OF THE DRAWINGS

The present invention will be understood and appreciated more fully from the following detailed description, taken in conjunction with the drawings in which:

FIG. 1 is a simplified schematic of the laser system. The components are: 1. A commercial fiber-coupled multimode diode laser with temperature control. 2. Polarization Controller (PC). 3. Coherent self-injection feedback. 4. Microresonator with a mechanical/temperature-based tuning system. 5. Tapered optical fiber. 6. Optical spectrum analyzer. 7. Photodetector. 8. Feedback control system. 9. Thermoelectric system for temperature control.

FIG. 2 is a graphical illustration of the laser spectrum at a temperature of 20° C. (solid line) The broadband laser emission consists of˜30 longitudinal modes with free spectral range (FSR) of˜0.3 nm. (dashed line) WGM-locked laser emission at a laser temperature of 20° C. with a side-mode suppression ratio of 25 dB.

FIG. 3 is a graphical illustration of tuning the WGM-locked laser over a range of 15 nm. The tunability is achieved by locking the laser to 19 different WGMs.

### DETAILED DESCRIPTION OF THE INVENTION

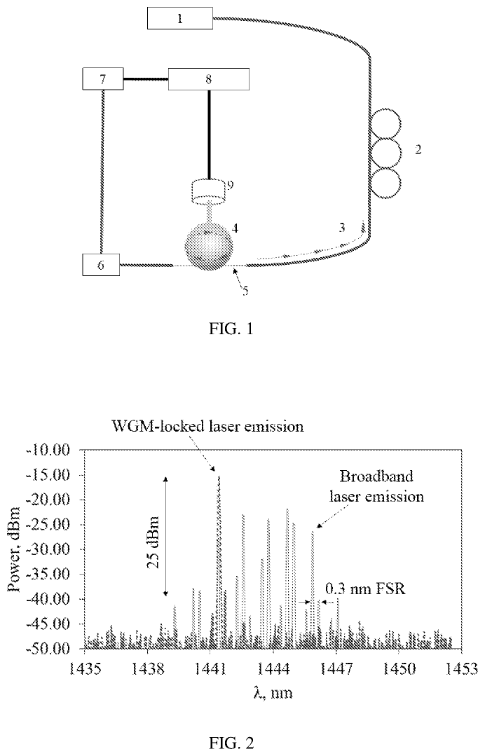

The schematic of the experimental setup is presented in FIG. 1. A commercial fiber-coupled multimode laser diode (single transverse mode) with a thermoelectric cooler is used. The laser beam is locked to a microresonator with high Q factor (10⁸≥Q≥10⁵) and with a feedback control system that tunes the microresonator's WGMs. Some of the light which is coupled into the microresonator is backscattered into the laser, providing feedback and locking the laser to a specific mode of the microresonator. In order to impede unwanted optical feedbacks to the laser source, FC-APC (fiber channel-angled physical contact) fiber connectors are used.

Generally, the low coherent light source excites multiple WGMs simultaneously; however, by fine tuning of the laser temperature, it is possible to shift the comb of the multimode laser lines relatively to the comb of the microresonator's WGMs so that only one WGM perfectly coincides with a laser line, and hence, to obtain single mode lasing via optical feedback of the laser mode.

In order to tune the wavelength of the narrowed single mode laser, the multimode laser source is locked to various WGMs of the microresonator; the WGMs to which the laser is locked can belong to different mode families. This is done by tuning the temperature of the laser source, which in turn, shifts the spectrum of the emitted light. As a consequence, the overlap between the spectral lines of the broadband laser and of the microsphere WGMs changes and different WGMs are excited. In addition, controlling the polarization of the laser source makes it possible to determine whether to excite TE (transverse electric) or TM (transverse magnetic) WGMs, and increases the number of possible modes to which the laser can couple, thus increasing the tunability of the laser.

The WGMs are tuned as well by controlling the temperature of the microresonator or by changing the shape of the microresonator (mechanically). In both cases, the optical path of the WGM is changed due to a change in the radius of the microresonator and in the effective refractive index of the mode. However, the mechanical route can provide a higher tuning speeds (>kHz) than can be achieved via temperature. Mechanical tuning of WGMs is achieved by applying a tensile stress on a microresonator with fiber tails at both ends, according to the following steps:
1. Hold one of the fiber tails of the microresonator on a static stage.
2. Hold one of the fiber tails of the microresonator on a single axis piezo system.
3. Bring a tapered fiber in contact with the microresonator to achieve optical coupling. The tapered fiber must be transverse to the fiber tails of the microresonator.
4. Tune the WGMs of the microresonator by applying a voltage signal to the piezo system.

Simultaneous control of the laser source temperature and of the microresonator WGMs can achieve a continuous tunability for the WGM-locked laser wavelength. “Dead zones” in the spectrum are avoided as long as the tuning range of the WGMs is larger than the spacing between all two adjacent modes. In that case, the continuous tuning is performed by simultaneous and equal shifting of the laser comb and of the WGMs comb after the locking is obtained.

The procedure of the laser locking and tuning is as follows;
1. Define the desired laser wavelength. The desired laser wavelength must exist within the tunability range of the device (˜15 nm).
2. Find the closest microresonator's WGM to the desired laser wavelength.
3. Bring the microresonator to its pre-modified (initial) conditions (temperature\tensile stress).
4. Set the temperature and polarization of the laser to lock the laser to that closest WGM.

5. Tune the laser temperature and the microresonator's WGM simultaneously using a feedback control system that ensures the stability of the locking during the spectral tuning process.
6. Stop the tuning process when the desired laser wavelength is obtained.

The ability to tune the single mode laser by locking it to different WGMs is achievable only where the ratio between the light wavelengths squared and the microresonator diameter is comprised between 1 and 100 for which the FSR is of˜0.2-20 nanometers, and the spacing between different WGMs is large. However, for larger microresonators, with a significantly smaller spacing between the WGMs, shifting the frequency comb of the laser to obtain single mode coupling to one mode of the dense WGMs of the microresonator is much more challenging, thus tuning this laser by locking to different individual modes, is not practical.

The linewidth of the WGM-locked single mode laser scales as 1/Q². However, increasing the microresonator Q factor narrows the linewidth of the WGM (Δv=v/Q), and thus decreases the spectral overlap between the WGM and the broadband laser emission. Consequently, the feedback power, which is essential for initiating the laser locking, is decreased. Reduction in the feedback power set a crucial limit to the laser locking procedure as it prevents the locking of the laser to certain WGMs for which the optical feedback is not strong enough to suppress the other laser modes. For that reason, the tunability range of the laser device is reduced as the Q factor of the microresonator increases. For a tunability range of more than 1 nm, microresonator with 10⁸≥Q≥10⁵ is required.

### EXAMPLE

The inventors used a fiber-coupled butterfly mounted multimode diode laser with a central wavelength at λ₀˜1445 nm and bandwidth of Δλ_{FWHM}˜5 nm (Qphotonics) (FWHM−full width at half maximum). The temperature of the laser may be controlled using a thermoelectric cooler with temperature tunability range of 0° C. -60° C. The tuning of the laser temperature shifts the central wavelength of the multimode laser beam by 0.5 nm per 1° C. The spectrum of the multimode laser at a temperature of 20° C. and output power of ˜2 mW is presented in FIG. 2 (solid line). The spectrum consists of˜30 longitudinal modes with FSR of 0.3 nm.

The laser beam may be locked to a silica microsphere with a diameter of˜30-35 μm, and a Q factor of Q˜10⁶. The WGM-locked laser emission at a laser temperature of 20° C. is shown in FIG. 2 (dashed line). The narrowed laser emission is concentrated in a single line (1441.4 nm) with a side-mode suppression ratio of 25 dB, being the wavelength where one of the laser lines coincides with a microresonator TE WGM.

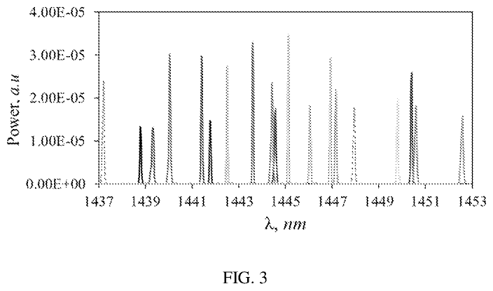

FIG. 3 shows 19 different WGM-locked laser modes over a range of˜15 nm, measured with an optical spectrum analyzer. The laser lines are obtained at different times, for different laser temperatures from 15° C. to 35° C., and different polarizations. By controlling the polarization of the laser it is possible to excite TE and TM WGMs, hence to improve the tunability of the laser. The laser lines presented in FIG. 3 are not equally spaced, as they represent WGMs of different mode families. As mentioned above, this featured may make the device suitable for applications such as three-dimensional digital holographic metrology, for which a laser source with non-uniformly spaced laser lines is advantageous.

TABLE 1
Relevant parameters in the example

| Parameter | Symbol | Value | |
|---|---|---|---|
| Laser central wavelength | λ₀ | 1445 | nm |
| Laser linewidth | Δλ_{FWHM} | 5 | nm |
| Laser temperature | | 0° C.-60° C. (0.5 | |
| tunability range | | nm per 1° C.) | |
| Laser output power | | 2 | mW |
| Laser Free spectral range | | 0.3 | nm |
| Microresonator | D | 30-35 | μm |
| (sphere) diameter | | | |

| | | |
|---|---|---|
| Microresonator Q factor | Q | 10⁶ |

1. An apparatus comprising:
a multimode (longitudinal), single transverse mode fiber coupled laser diode,
an optical fiber with a tapered region, coupled to the said diode,
a microresonator in contact with the tapered region of said fiber,
a polarization controller that controls the polarization of the light in the tapered region, a first temperature controller that controls temperature and wavelength of the laser diode,
a device for modifying the whispering gallery modes (WGM) distribution of the microresonator, and
a control feedback system that adjusts the modes distribution of the microresonator.

2. The apparatus according to claim 1, wherein said control feedback system is configured to ensure lasing stability.

3. The apparatus according to claim 2, wherein said control feedback system is configured to continuously scan said WGM-locked laser diode wavelength through said first temperature controller.

4. The apparatus according to claim 1, wherein said device is a temperature controller.

5. The apparatus according to claim 1, wherein said device is based on a mechanically tunable microresonator with two stretchable fiber tails and a piezo system.

6. The apparatus according to claim 1, wherein a ratio between the light wavelengths squared and the microresonator diameter is between 1 and 100, and wherein the quality factor (Q factor) is between 10⁵ and 10⁸.

7. A method to obtain a tunable long coherence laser, comprising:
defining a desired laser wavelength, said desired laser wavelength being within a tunability range of said tunable long coherence laser;
finding the closest microresonator's WGM to the desired laser wavelength;
bringing the microresonator to its pre-modified initial conditions of temperature or tensile stress;
setting the temperature and polarization of the laser to lock the laser to that closest WGM;
tuning the laser temperature and the microresonator's WGM simultaneously using a feedback control system that ensures the stability of the locking during the spectral tuning process; and
stopping the tuning process when the desired laser wavelength is obtained.

8. The method according to claim 7, wherein the laser is locked to a microresonator with mechanical tuning, according to the following steps:
holding one of the fiber tails of the microresonator on a static stage;
holding one of the fiber tails of the microresonator on a single axis piezo system;
bringing a tapered fiber in contact with the microresonator to achieve optical coupling, wherein said tapered fiber is transverse to the fiber tails of the microresonator; and
tuning the WGMs of the microresonator by applying a voltage signal to the piezo system.
